(19) United States
(12) Patent Application Publication
(10) Pub. No.: US 2009/0236759 A1
(43) Pub. Date: Sep. 24, 2009

(54) CURABLE SILICONE RUBBER COMPOSITION AND SEMICONDUCTOR DEVICE

(76) Inventor: Tsutomu KASHIWAGI, Annaka-shi (JP)

Correspondence Address: BIRCH STEWART KOLASCH & BIRCH, PO BOX 747, FALLS CHURCH, VA, 22040-0747, US

(21) Appl. No.: 12/408,934

(22) Filed: Mar. 23, 2009

(30) Foreign Application Priority Data
Mar. 24, 2008 (JP) 2008-075644

(51) Int. Cl. H01L 23/29; C08L 83/06

(52) U.S. Cl. 257/791; 525/478; 257/E23.12

(57) ABSTRACT

A curable silicone rubber composition, comprising: (A) an organopolysiloxane containing two or more alkenyl groups within each molecule, (B) an organohydrogenpolysiloxane having two or more hydrogen atoms bonded to silicon atoms within each molecule, (C) a metal-based condensation reaction catalyst, (D) a platinum group metal-based addition reaction catalyst, and (E) an adhesion-imparting agent, wherein among the refractive indices of component (A), a mixture of component (A) and component (B), and component (E), the difference between the maximum refractive index and the minimum refractive index is not more than 0.03.

### CROSS REFERENCE

This application claims benefits of Japanese Patent Application No. 2008-75644 filed on Mar. 24, 2008, the contents of which are hereby incorporated by reference.

### BACKGROUND OF THE INVENTION

1. Field of the Invention

The present invention relates to an addition-curable silicone rubber composition, and relates particularly to a curable silicone rubber composition that exhibits favorable adhesion to thermoplastics such as PPA (polyphthalamide resins) and liquid crystal polymers (LCP), and to electrode noble metals such as silver and gold. The invention also relates to a semiconductor device encapsulated with a cured product of the curable silicone rubber composition.

2. Description of the Prior Art

Silicone rubber compositions form cured products that exhibit excellent properties of weather resistance and heat resistance and the like, as well as superior rubber-like properties such as hardness and elongation, and are therefore used in a wide variety of applications.

In recent years, highly heat-resistant thermoplastics such as PPA (polyphthalamide resins) and LCP (liquid crystal polymers) have been investigated as potential materials for all manner of packages. Further, metals such as Ag, Au, Ni and Pd are used for frames and electrodes. However, securely bonding a silicone rubber to these thermoplastics or metals has proven difficult. Furthermore, the soldering conditions employed within devices formed using these types of materials has now been changed to high-temperature soldering that contains no lead. Accordingly, a problem has arisen in that high-temperature stress, temperature cycling, and storage under high temperature and high humidity tends to result in ready peeling at the interface between the package and the silicone resin. Furthermore, another problem also occurs in that the heat generated from LEDs (light emitting diodes) causes degradation and hardening of the silicone resin, leading to cracking of the resin (for example, see Patent Document 1).

In most addition-curable silicone rubber compositions, any of a variety of silane coupling agents are added to improve the adhesion, but coupling agents that include a large amount of epoxy groups have a high refractive index, resulting in a loss of transparency for the composition. Furthermore, vigorous reaction can result in discoloration or clouding of the composition, meaning such compositions are unsuited to optical applications and the like. An addition-curable silicone rubber composition disclosed in Patent Document 2 exhibits superior adhesion to metals such as Ag, Au, Ni and Pd, but in terms of its anti-discoloration and light resistance properties, the composition is unsatisfactory for optical applications.

[Patent Document 1] JP 2003-174059A

[Patent Document 2] US2006/0270792A1

### SUMMARY OF THE INVENTION

The present invention has been developed in light of the above circumstances, and has an object of providing a curable silicone rubber composition which generates satisfactory adhesive strength to all manner of package materials composed of thermoplastics such as PPA (polyphthalamides) and LCP (liquid crystal polymers), which are inherently difficult to bond, and to electrodes composed of metals such as Ag, Au, Ni and Pd, and which yields a cured product that has favorable transparency. Another object of the present invention is to provide a semiconductor device that has been encapsulated with a cured product of such a composition.

As a result of intensive investigation aimed at achieving the above objects, the inventors of the present invention discovered that a curable silicone rubber composition for which the difference between the refractive indices of certain predetermined organopolysiloxane components was not more than a predetermined value generated good adhesive strength even to substrates that are inherently difficult to bond, including all manner of package materials composed of thermoplastics such as PPA and LCP, and electrodes and the like composed of metals such as Ag, Au, Ni and Pd, and also formed a cured product having favorable transparency. The inventors also discovered that a semiconductor device encapsulated with such a cured product displayed excellent reliability, and based on these findings, they were able to complete the present invention.

In other words, the present invention provides a curable silicone rubber composition, comprising:

(A) a linear organopolysiloxane (A-1) represented by a general formula (1) shown below, having a viscosity at 25° C. within a range from 10 to 1,000,000 mPa·s,

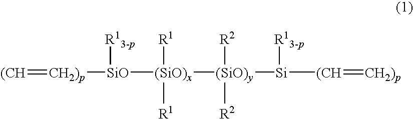

wherein each R¹ represents, independently, an unsubstituted or substituted monovalent hydrocarbon group, each R² represents, independently, an unsubstituted or substituted monovalent hydrocarbon group having no aliphatic unsaturated bonds, x and y each represents either 0 or a positive integer, provided that x+y is a number that yields a viscosity at 25° C. for the organopolysiloxane of 10 to 1,000,000 mPa·s, and p is an integer from 1 to 3, or

a mixture of the organopolysiloxane (A-1) and a resin-structure organopolysiloxane (A-2) composed of SiO₂ units, R³ₖR⁴ₚSiO_{0.5} units and R³_{q}R⁴ᵣSiO_{0.5} units, wherein R³ represents a vinyl group or allyl group, R⁴ represents a monovalent hydrocarbon group containing no aliphatic unsaturated bonds, k is 2 or 3 and p is 0 or 1, provided that k+p=3, q is 0 or 1 and r is 2 or 3, provided that q+r=3,

(B) an organohydrogenpolysiloxane having two or more SiH groups within each molecule,

(C) a metal-based condensation reaction catalyst,

(D) a platinum group metal-based addition reaction catalyst, and

(E) an organopolysiloxane-based adhesion-imparting agent containing at least two types of functional groups selected from the group consisting of alkenyl groups, alkoxy groups and epoxy group, wherein

among refractive indices of component (A), a mixture of component (A) and component (B), and component (E), a difference between a maximum refractive index and a minimum refractive index is not more than 0.03.

The curable silicone rubber composition of the present invention generates effective adhesion to substrates such as Ag and PPA that have proven extremely difficult to bond until now, and a semiconductor device encapsulated with a cured product of this composition is capable of withstanding severe reliability testing.

### BRIEF DESCRIPTION OF THE DRAWINGS

FIG. 1 is a schematic perspective view describing a method of measuring the shear adhesive strength in examples of the present invention.

FIG. 2 is a schematic cross-sectional view describing a package shape used in a high-humidity reflow test in examples of the present invention.

### DETAILED DESCRIPTION OF THE PREFERRED EMBODIMENTS

### [(A-1) Linear Organopolysiloxane]

The component (A-1) has a viscosity at 25° C. that is typically within a range from 10 to 1,000,000 mPa·s, and preferably from 100 to 100,000 mPa·s. This viscosity can be measured using a rotational viscometer. This linear organopolysiloxane is represented by a general formula (1) shown below, and includes vinyl groups on the silicon atoms at both molecular chain terminals. The organopolysiloxane may include some branched structures (trifunctional siloxane units) within the molecular chain, in an amount that does not impair the effects of the present invention.

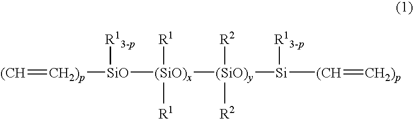

(wherein each R¹ represents, independently, an unsubstituted or substituted monovalent hydrocarbon group, each R² represents, independently, an unsubstituted or substituted monovalent hydrocarbon group having no aliphatic unsaturated bonds, x and y each represents either 0 or a positive integer, provided that x+y is a number that yields a viscosity at 25° C. for the organopolysiloxane of 10 to 1,000,000 mPa·s, and p is an integer from 1 to 3)

In the general formula (1), R¹ is preferably a monovalent hydrocarbon group of 1 to 10 carbon atoms, and particularly 1 to 6 carbon atoms, and specific examples include alkyl groups such as a methyl group, ethyl group, propyl group, isopropyl group, butyl group, isobutyl group, tert-butyl group, pentyl group, neopentyl group, hexyl group, cyclohexyl group, octyl group, nonyl group or decyl group; aryl groups such as a phenyl group, tolyl group, xylyl group or naphthyl group; aralkyl groups such as a benzyl group, phenylethyl group or phenylpropyl group; alkenyl groups such as a vinyl group, allyl group, propenyl group, isopropenyl group, butenyl group, hexenyl group, cyclohexenyl group or octenyl group; and groups in which some or all of the hydrogen atoms within one of the above hydrocarbon groups have been replaced with a halogen atom such as a fluorine atom, bromine atom or chlorine atom, or a cyano group or the like, including halogenated alkyl groups such as a chloromethyl group, chloropropyl group, bromoethyl group or trifluoropropyl group, and a cyanoethyl group. R¹ is preferably a methyl group, phenyl group or vinyl group.

Furthermore, R² is also preferably a monovalent hydrocarbon group of 1 to 10 carbon atoms, and particularly 1 to 6 carbon atoms, and specific examples of R² include the same groups as those listed above for R¹, but excluding those groups containing an aliphatic unsaturated bond such as the alkenyl groups. R² is preferably a methyl group or a phenyl group.

Examples of the component (A-1) include the compounds shown below.

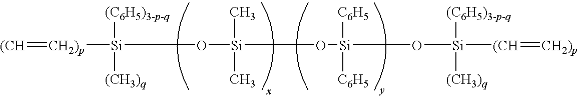

In this formula, p represents 1 or 2, q is an integer of 0 to 3, and x and y are both integers of 0 or greater that satisfy 0<x+y≦2,000, preferably 5≦x+y≦1,500, and still more preferably 10≦x+y≦1,000, and also satisfy 0≦y/(x+y)≦0.5, and preferably 0≦y/(x+y)≦0.35. Specific examples of this component (A-1) include the compounds shown below.

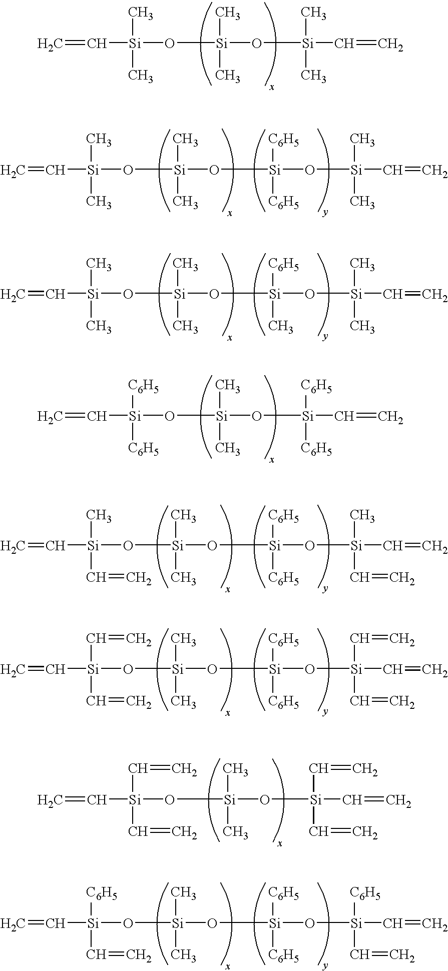

(wherein, x and y are as defined above)

### [(A-2) Resin-Structure Organopolysiloxane]

Furthermore, in the present invention, a resin-structure organopolysiloxane may be used in combination with the organopolysiloxane described above. This resin-structure (namely, three dimensional network-type structure) organopolysiloxane is composed of SiO₂ units, R³ₖR⁴ₚSiO_{0.5} units and R³_{q}_{R}⁴ᵣSiO_{0.5} units (wherein R³ represents a vinyl group or allyl group, R⁴ represents an unsubstituted or substituted monovalent hydrocarbon group containing no aliphatic unsaturated bonds, k is 2 or 3 and p is 0 or 1, provided that k+p=3, and q is 0 or 1 and r is 2 or 3, provided that q+r=3). Examples of the monovalent hydrocarbon group R⁴ include the same hydrocarbon groups of 1 to 10 carbon atoms, and preferably 1 to 6 carbon atoms, as those listed above for R².

In this resin-structure organopolysiloxane, if the SiO₂ units are termed “a units”, the R³ₖR⁴ₚSiO_{0.5} units are termed “b units”, and the R³_{q}R⁴ᵣSiO_{0.5} units are termed “c units”, then the respective molar proportions of these units preferably satisfy the equations shown below.

(b+c)/a=0.3 to 2, and particularly 0.7 to 1.5

c/a=0.1 to 2, and particularly 0.2 to 1.5

Furthermore, this organopolysiloxane preferably has a weight average molecular weight, measured by GPC and referenced against polystyrene standards, that falls within a range from 500 to 10,000.

In addition to the a units, b units and c units mentioned above, the resin-structure organopolysiloxane may also include small amounts of bifunctional siloxane units and trifunctional siloxane units (namely, organosilsesquioxane units), provided inclusion of these units does not impair the effects of the present invention.

This type of resin-structure organopolysiloxane can be synthesized easily, by combining the compounds that act as the source materials for each of the units, in amounts that yield the molar proportions described above, and then conducting a cohydrolysis in the presence of an acid or the like.

Examples of the source material for the a units include sodium silicate, alkyl silicates, polyalkyl silicates, and silicon tetrachloride.

Examples of the source material for the b units include the compounds shown below.

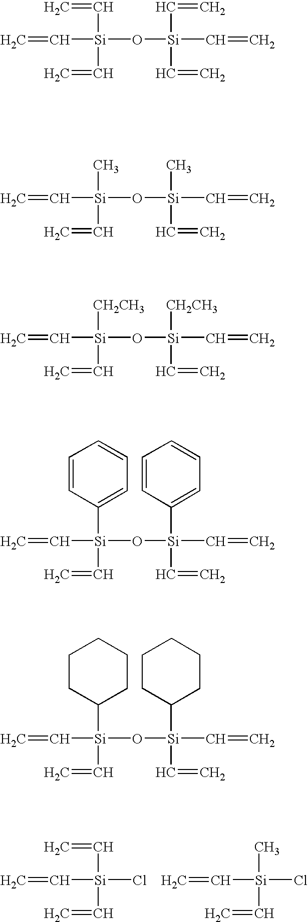

Moreover, examples of the source material for the c units include the compounds shown below.

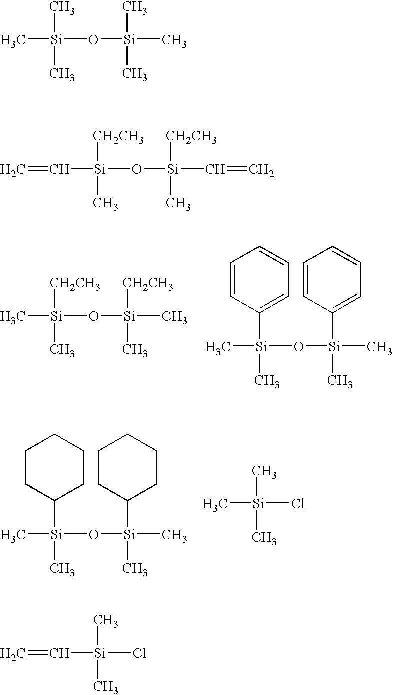

The above resin-structure organopolysiloxane (A-2) has the effects of improving the physical strength and of reducing surface tack of the cured product. The component (A) preferably comprises 20 to 70% by mass, and more preferably 30 to 60% by mass, of the component (A-2). If the amount of the resin-structure organopolysiloxane is too high, then the viscosity of the composition may increase dramatically, or the cured product may become prone to cracking.

### [(B) Organohydrogenpolysiloxane]

The organohydrogenpolysiloxane (B) functions as a cross-linking agent, wherein the cured product is formed as a result of an addition reaction between the SiH groups within this component and the alkenyl groups within component (A). This organohydrogenpolysiloxane contains two or more, and preferably three or more, SiH groups within each molecule. Examples of the organohydrogenpolysiloxane include compounds represented by an average composition formula (2) shown below:

Hₐ(R⁵)_{b}SiO_{(4-a-b)/2} (2)

(wherein, R⁵ represents identical or different, unsubstituted or substituted monovalent hydrocarbon groups that contain no aliphatic unsaturated bonds, and a and b are numbers that satisfy the formulas: 0.001≦a<2, 0.7≦b<2, and 0.8≦a+b≦3), which contain at least two, and preferably 3 or more, SiH groups within each molecule.

In the above formula (2), R⁵ is preferably a monovalent hydrocarbon group of 1 to 10 carbon atoms, and particularly from 1 to 7 carbon atoms, and specific examples include those groups listed above in relation to the substituent group R² within the aforementioned general formula (1), including lower alkyl groups such as a methyl group and aryl groups such as a phenyl group. Furthermore, a and b are preferably numbers that satisfy the formulas: 0.05≦a≦1, 0.8≦b≦2, and 1≦a+b≦2.7. There are no particular restrictions on the positions of the hydrogen atoms bonded to silicon atoms, which may be at the molecular terminals or at non-terminal positions within the molecular chain.

Specific examples of the above organohydrogenpolysiloxane include tris(dimethylhydrogensiloxy)methylsilane, tris(dimethylhydrogensiloxy)phenylsilane, 1,1,3,3-tetramethyldisiloxane, 1,3,5,7-tetramethylcyclotetrasiloxane, methylhydrogenpolysiloxane with both terminals blocked with trimethylsiloxy groups, copolymers of dimethylsiloxane and methylhydrogensiloxane with both terminals blocked with trimethylsiloxy groups, dimethylpolysiloxane with both terminals blocked with dimethylhydrogensiloxy groups, copolymers of dimethylsiloxane and methylhydrogensiloxane with both terminals blocked with dimethylhydrogensiloxy groups, copolymers of methylhydrogensiloxane and diphenylsiloxane with both terminals blocked with trimethylsiloxy groups, copolymers of methylhydrogensiloxane, diphenylsiloxane and dimethylsiloxane with both terminals blocked with trimethylsiloxy groups, copolymers composed of (CH₃)₂HSiO_{1/2} units and SiO_{4/2} units, and copolymers composed of (CH₃)₂HSiO_{1/2} units, SiO_{4/2} units, and (C₆H₅)SiO_{3/2} units.

Examples of the organohydrogenpolysiloxane (B) include the linear compounds shown below.

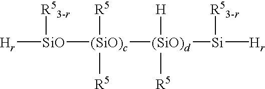

In this formula, R⁵ is as defined above, and r represents 0 or 1. c and d are integers that satisfy 0≦c≦500 and preferably 0≦c≦200, and 0≦d≦500 and 0≦d≦200 respectively, provided that when r is 0, d is an integer of 2 or greater. (c+d) is an integer that satisfies 1≦c+d≦1,000 and preferably 1≦c+d≦300. Specific examples of the organohydrogenpolysiloxane (B) include the compounds listed below.

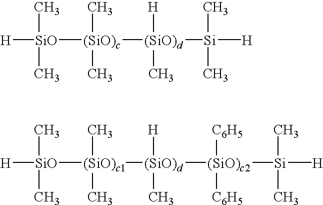

(wherein c1+c2=c)

Further examples of the organohydrogenpolysiloxane (B) include the branched compounds shown below.

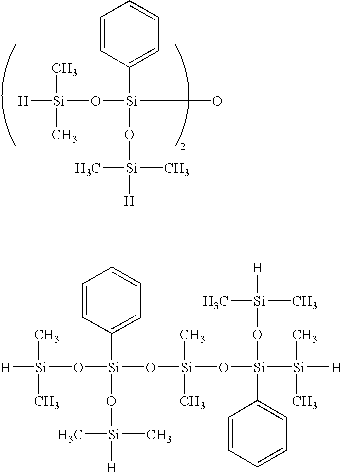

The molecular structure of the organohydrogenpolysiloxane of component (B) may be a linear, cyclic, branched, or three dimensional network-type structure. The number of silicon atoms within a single molecule (or the polymerization degree) is typically within a range from 3 to 1,000, and preferably from approximately 3 to 300.

This type of organohydrogenpolysiloxane can normally be obtained either by hydrolysis of a chlorosilane such as R⁵SiHCl₂, (R⁵)₃SiCl, (R⁵)₂SiCl₂ or (R⁵)₂SiHCl (wherein, R⁵ is as defined above), or by equilibration of the siloxane obtained upon hydrolysis.

The blend amount of this organohydrogenpolysiloxane must be effective in curing the component (A), and is typically used in an amount that provides a molar ratio of 0.7 to 4.0 mols, preferably 1.0 to 3.0 mols, and still more preferably 1.2 to 2.0 mols, of SiH groups per 1 mol of all the alkenyl groups (such as vinyl groups) within the component (A). If the molar ratio is less than the lower limit of the above range, then obtaining a cured product may become difficult, whereas if the molar ratio exceeds the upper limit, large amounts of unreacted SiH groups tends to remain within the cured product, which can cause changes in the physical properties of the rubber over time.

### [(C) Metal-Based Condensation Catalyst]

The metal-based condensation catalyst (C) causes reaction of the functional groups such as the epoxy groups or alkoxy groups within the adhesion-imparting agent (E). The metal within the catalyst is preferably aluminum or zirconium. Under heat or the like, the condensation catalyst may cause cleavage of the silicone, and therefore depending on the conditions under which the composition is to be stored and used, a zirconium-based catalyst may be more preferable. Examples of aluminum-based catalysts include aluminum trihydroxide, aluminum alcoholates, aluminum acylates, aluminum acylate salts, aluminosiloxy compounds, and aluminum metal chelate compounds, and of these, aluminum chelate compounds are preferred. Specific examples of catalysts formed from this type of aluminum chelate compound include the commercially available products ACS and Chelope EB-2 (manufactured by Hope Chemical Co., Ltd.).

Examples of zirconium catalysts include zirconium alkoxides such as zirconium tetra-normal-propoxide and zirconium tetra-normal-butoxide, zirconium chelates such as zirconium tributoxy monoacetonate, zirconium tributoxy monoacetylacetonate and zirconium tetraacetylacetonate, and zirconium acylates such as zirconium tributoxy monostearate and zirconium acetate.

The blend amount of the metal-based condensation catalyst is preferably within a range from 0.005 to 10 parts by mass, and more preferably from 0.05 to 2 parts by mass, relative to 100 parts by mass of a combination of the components (A) and (E). If this blend amount is less than the lower limit of this range, then a satisfactory effect may not be obtained, whereas a blend amount that exceeds the upper limit may have an adverse effect on the curing properties (such as the hardness and external appearance) of the resin.

### [(D) Platinum Group Metal-Based Addition Reaction Catalyst]

The platinum group metal-based catalyst (D) is added to promote the addition curing reaction within the composition of the present invention. Examples of the component (D) include platinum-based, palladium-based, and rhodium-based catalysts, although from the viewpoint of cost, platinum-based catalysts such as platinum, platinum black and platinic chlorides are preferred, including H₂PtCl₆.mH₂O, K₂PtCl₆, KHPtCl₆.mH₂O, K₂PtCl₄, K₂PtCl₄.mH₂O, PtO₂.mH₂O, (wherein m represents a positive integer), as well as complexes of these compounds with hydrocarbons such as olefins, alcohols, or vinyl group-containing organopolysiloxanes. Either a single catalyst or a combination of two or more different catalysts may be used.

The blend amount of this catalyst component need only be a so-called effective catalytic amount, and a typical amount, calculated as an equivalent mass of the platinum group metal relative to the mass of the component (A), is within a range from 0.1 to 1,000 ppm, and preferably from 0.5 to 200 ppm.

### [(E) Adhesion-Imparting Agent]

The adhesion-imparting agent (E) is an organopolysiloxane containing at least two types of functional groups selected from the group consisting of alkenyl groups, alkoxy groups and epoxy group. Examples of the alkenyl groups include a silicon atom-bonded vinyl group or allyl group. Examples of the alkoxy groups include a methoxy group, ethoxy group, or a trimethoxysilyl group bonded to a silicon atom via a silethylene group. Examples of the epoxy group-containing groups include a glycidoxypropyl group or a 3,4-epoxycyclohexylethyl group. The organopolysiloxane is typically a linear or cyclic organopolysiloxane containing 4 to 100 silicon atoms, preferably 4 to 50 silicon atoms, and still more preferably approximately 4 to 20 silicon atoms, and having a polystyrene-referenced weight average molecular weight of 150 to 4,000.

Examples of the adhesion-imparting agent (E) include the compounds represented by the formulas shown below.

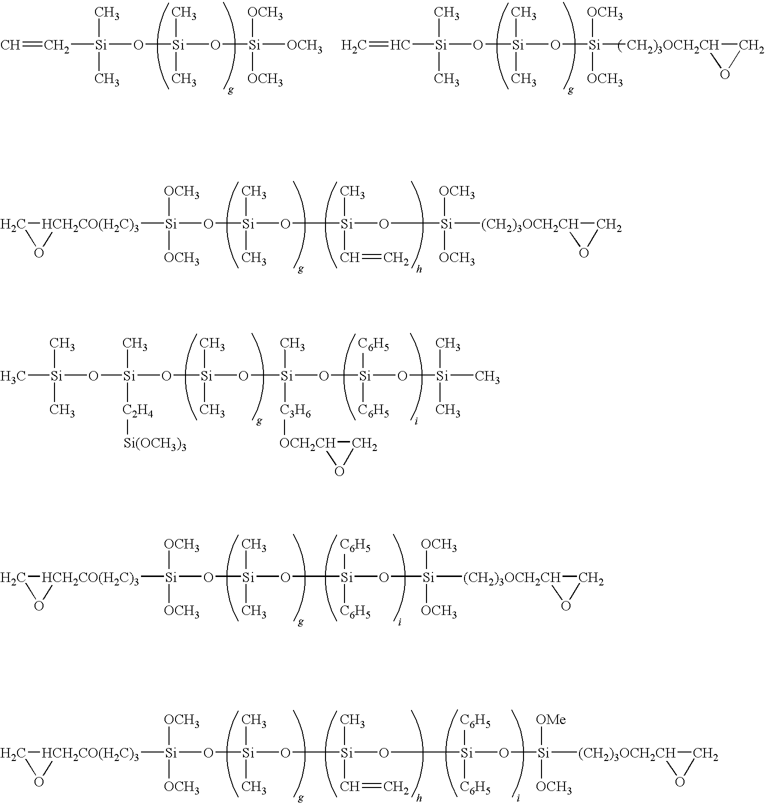

(wherein g, h and i are positive integers for which g+h+i is within a range from 1 to 50 and preferably from 4 to 20)

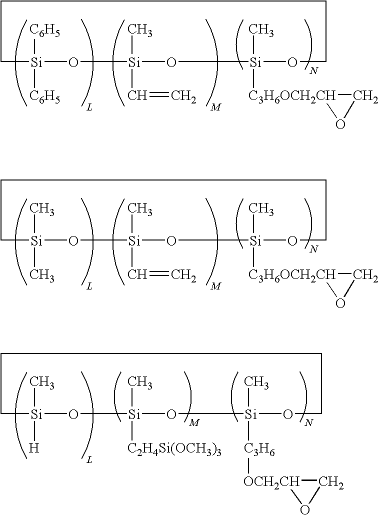

(wherein L, M and N are positive integers for which L+M+N is within a range from 3 to 8 and preferably from 4 to 6)

The blend amount of the adhesion-imparting agent (E) is preferably within a range from 0.01 to 10 parts by mass, more preferably from 0.01 to 5 parts by mass, and most preferably from 0.1 to 3 parts by mass, per 100 parts by mass of the component (A). If the blend amount of the component (E) is less than the lower limit of this range, then the adhesion of the composition to substrates tends to deteriorate, whereas a blend amount that is too large may have an adverse effect on the hardness and surface tack of the cured product.

In the present invention, the difference between the maximum refractive index and the minimum refractive index among the refractive indices of the component (A), a mixture of the component (A) and the component (B), and the component (E) is typically not more than 0.03, preferably not more than 0.02, and still more preferably 0.015 or less. Here, the term “refractive index” refers to the refractive index n_{D} at sodium-D light at 25° C., and can be measured using an Abbe refractometer. By ensuring that this difference between the refractive indices is not more than the above value, the compatibility of the components can be improved, and the transparency of the resulting cured product increases, making the composition ideal for encapsulating light emitting elements.

Examples of preferred combinations of the component (A), the component (B) and the component (E) for satisfying the above refractive index condition include combinations in which neither the component (A) nor the component (E) contain any aromatic groups, and combinations in which at least one of the component (A), the component (B) and the component (E) contains aromatic groups, and in which the maximum and minimum mol % values for aromatic groups within these components satisfies the formula shown below.

[(maximum value−minimum value)/maximum value]≦0.3

In the latter case, phenyl groups are preferred as the aromatic groups, and the mol % value refers to the ratio, expressed as a percentage, of the number of mols of aromatic groups relative to the total number of mols of silicon atom-bonded substituents.

### [Other Additives]

In addition to the components (A) to (E) described above, if required, the composition of the present invention may also include a variety of conventional additives. For example, reinforcing inorganic fillers such as fumed silica and fumed titanium dioxide, and non-reinforcing inorganic fillers such as calcium carbonate, calcium silicate, titanium dioxide, ferric oxide, carbon black and zinc oxide may be added to the composition in amounts that do not impair the effects of the present invention, and preferably in amounts of 1 to 50% by mass relative to the total mass of the composition.

A silicone rubber composition of the present invention is prepared by mixing each of the above components uniformly together, although in order to ensure curing does not proceed, the composition is usually stored as two separate liquids, and these two liquids are then mixed together and cured at the time of use. Needless to say, a one-pot composition containing a small amount of an added curing inhibitor such as an acetylene alcohol is also possible. Further, in the case of a two-pot composition, including the component (B) and the component (C) in the same liquid must be avoided in order to prevent the possibility of dehydrogenation reactions.

The viscosity of the thus obtained silicone rubber composition at 25° C., measured using a rotational viscometer, is typically within a range from 100 to 10,000,000 mPa·s, and is preferably from approximately 300 to 500,000 mPa·s.

If required, the silicone rubber composition of the present invention can be cured immediately by heating, and because the composition has a high degree of transparency and bonds strongly to package materials such as LCPs and metal substrates, it can be used widely as a material for coating or encapsulating semiconductor chips such as LED, photodiodes, CCD and CMOS.

Although there are no particular restrictions on the curing conditions used for the composition of the present invention, curing is typically conducted at 40 to 250° C., and preferably at 60 to 200° C., for a period of 5 minutes to 10 hours, and preferably 30 minutes to 6 hours.

In order to coat or encapsulate a semiconductor chip mounted on a support, the composition of the present invention is coated onto the semiconductor chip, subsequently molded into the desired shape, and then cured by heating.

### EXAMPLES

The present invention is described in further detail below using a series of examples and comparative examples, although the present invention is in no way limited by these examples. In the following examples, the units “parts” refer to “parts by mass”, Me represents a methyl group, Ph represents a phenyl group, and Vi represents a vinyl group. Refractive index values refer to the refractive index n_{D} relative to sodium-D light measured at 25° C. using an Abbe refractometer.

### Example 1

50 parts of a polysiloxane (VF) represented by a formula (i) shown below:

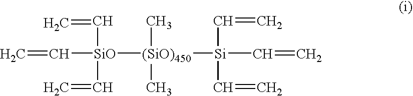

was mixed with 50 parts of a resin-structure vinylmethylsiloxane (VMQ) composed of 50 mol % of SiO₂ units, 42.5 mol % of (CH₃)₃SiO_{0.5} units and 7.5 mol % of Vi₃SiO_{0.5} units. The refractive index of the resulting mixture was 1.41. This mixture was then mixed with an organohydrogenpolysiloxane represented by formula (ii) shown below,

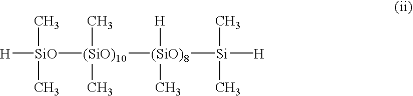

which was added in sufficient amount to provide 1.5 mols of SiH groups per mol of vinyl groups within the combination of the VF and VMQ components. To the resulting mixture (refractive index: 1.41) were added and mixed 0.05 parts of a solution of octyl alcohol-modified chloroplatinic acid (platinum concentration: 2% by mass), 0.1 parts of an aluminum chelate catalyst ACS (a product name, manufactured by Hope Chemical Co., Ltd.)., and 1 part of an adhesion-imparting agent (refractive index: 1.42) represented by a formula shown below:

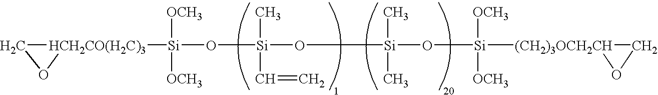

thus yielding a silicone rubber composition.

### Example 2

With the exception of replacing the adhesion-imparting agent used in example 1 with an adhesion-imparting agent having a refractive index of 1.43, represented by a formula shown below:

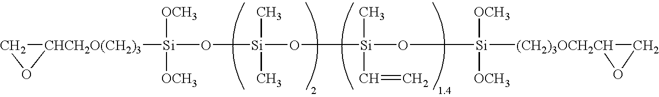

a silicone rubber composition was prepared in the same manner as example 1.

### Example 3

A mixture (refractive index: 1.51) was prepared by mixing 100 parts of a vinylsiloxane (refractive index: 1.51) represented by a formula shown below, and 8 parts of a hydrogensiloxane represented by a formula shown below.

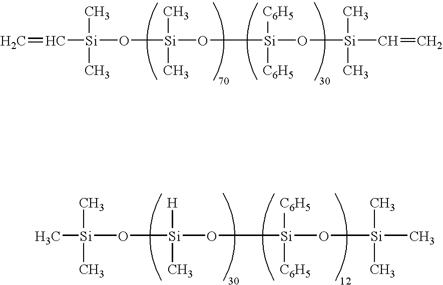

To 100 parts of this mixture were added 0.05 parts of a solution of octyl alcohol-modified chloroplatinic acid (platinum concentration: 2% by mass), 0.1 parts of an aluminum chelate catalyst ACS (a product name, manufactured by Hope Chemical Co., Ltd.)., and 1 part of an adhesion-imparting agent (refractive index: 1.50) represented by a formula shown below:

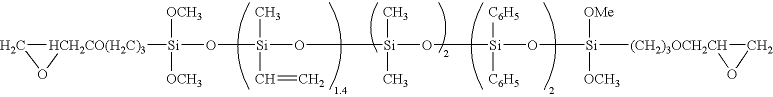

thus forming a silicone rubber composition in the same manner as example 1.

### Example 4

50 parts of a polysiloxane (VF) represented by a formula (i) shown below:

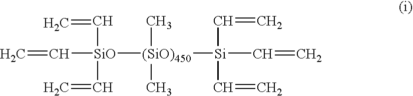

was mixed with 50 parts of a resin-structure vinylmethylsiloxane (VMQ) composed of 50 mol % of SiO₂ units, 42.5 mol % of (CH₃)₃SiO_{0.5} units and 7.5 mol % of Vi₃SiO_{0.5} units. The refractive index of the resulting mixture was 1.41. This mixture was then mixed with an organohydrogenpolysiloxane represented by formula (ii) shown below,

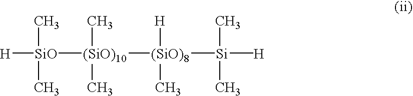

which was added in sufficient amount to provide 1.5 mols of SiH groups per mol of vinyl groups within the combination of the VF and VMQ components. To the resulting mixture (refractive index: 1.41) were added and mixed 0.05 parts of a solution of octyl alcohol-modified chloroplatinic acid (platinum concentration: 2% by mass), 0.1 parts of a zirconium alkoxide (Orgatix ZA60 (a product name), manufactured by Matsumoto Trading Co., Ltd.), and 1 part of an adhesion-imparting agent (refractive index: 1.42) represented by a formula shown below:

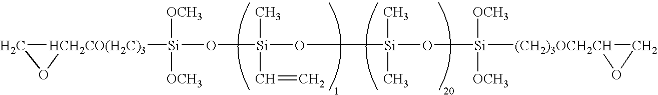

thus yielding a silicone rubber composition.

### Comparative Example 1

With the exception of not adding the aluminum metal chelate catalyst ACS, a silicone rubber composition was prepared in the same manner as example 1.

### Comparative Example 2

With the exception of not adding the aluminum metal chelate catalyst ACS, a silicone rubber composition was prepared in the same manner as example 3.

### Comparative Example 3

With the exception of replacing the adhesion-imparting agent used in example 1 with the adhesion-imparting agent used in example 3, a silicone rubber composition was prepared in the same manner as example 1.

### [Evaluation Methods]

Each of the compositions was evaluated using the methods described below. The results are shown in Tables 1 to 3.

### <External Appearance, Light Transmittance, Tensile Strength, Hardness, Elongation>

The composition was heat-molded for 4 hours at 150° C. to form a cured product of thickness 1 mm, and the external appearance of the cured product was evaluated by visual inspection. Further, the light transmittance (450 nm) was measured using an absorption meter. Furthermore, the tensile strength, hardness (measured using a type-A spring tester) and elongation were measured in accordance with the methods prescribed in JIS K 6301.

### <PPA Shear Adhesive Strength>

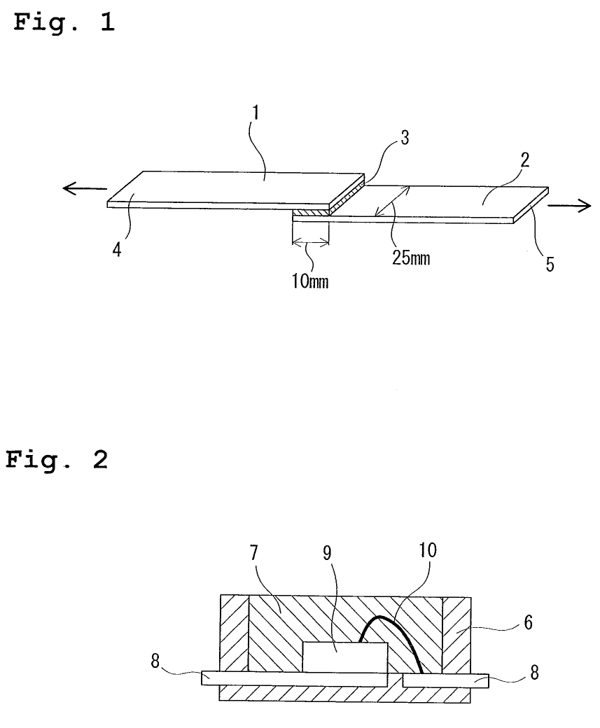

As shown in FIG. 1, two substrate fragments 1 and 2 formed from PPA (polyphthalamide resin) strips of width 25 mm were bonded together by overlapping the ends of the two fragments to a length of 10 mm with a 1 mm thick composition layer 3 provided between the overlapped ends, and then curing the composition layer 3 by heat-curing for 4 hours at 150° C. The resulting test piece was left to stand at room temperature for at least 12 hours, and the tensile shear adhesive strength was then measured by using a pull tester to pull the two ends 4 and 5 of the test piece in the directions shown by the arrows.

### <Cohesive Failure Rate>

The fractured surface of the test piece following measurement of the shear adhesive strength was evaluated by determining the ratio of the surface area across which cohesive failure occurred (that is, those areas where the PPA and the silicone rubber (the cured product of the composition layer 3) did not undergo interface separation, but rather the silicone rubber itself fractured) relative to the total surface area of the fractured surface, and this ratio (as a percentage) was recorded as the cohesive failure rate.

### <Reflow Resistance>

The silicone rubber composition was injected into the dummy package shown in FIG. 2 (product name: Amodel, manufactured by Solvay S.A.) and was then cured at 150° C. for 4 hours, and a high-humidity reflow test was then conducted in accordance with MSL level 2. In FIG. 2, a semiconductor chip 9 is mounted on a silver-plated pad of a lead frame 8 positioned inside the recess of a package 6 formed from PPA (polyphthalamide resin), and this semiconductor chip 9 is connected to an electrode via a wire 10. The silicone rubber composition 7 was injected into the recess and cured, thus encapsulating the semiconductor chip 9 and the wire 10. The resulting device was placed inside a thermostatic chamber at 85° C. and 85% RH, a 20 mA current was supplied to the chip 9 for a predetermined period of time, and the composition 7 was inspected for peeling. Furthermore, a high-humidity reflow test was conducted in accordance with the MSL test methods, by allowing the device to stand for 16 hours in an atmosphere at 60° C. and 90% RH to ensure thorough moisture absorption, passing the device through an IR reflow oven at a maximum temperature of 260° C., and then returning the device to 85° C. and 85% RH and visually inspecting the device for the presence of peeling or cracking for a period up to 1,000 hours. The results are shown in Table 3. In Table 3, the numerical values represent the proportion (%) of devices in which a fault was detected for a sample size of n=20.

TABLE 1

| | Example 1 | Example 2 | Example 3 | Example 4 |
|---|---|---|---|---|
| SiH/SiVi | 1.5 | 1.5 | 1.5 | 1.5 |
| External appearance | colorless and | colorless and | colorless and | colorless and |
| | transparent | transparent | transparent | transparent |
| Light transmittance % | 95 | 98 | 98 | 95 |
| Refractive index n_{D} of (A) + (B) | 1.41 | 1.41 | 1.51 | 1.41 |
| Curing conditions | 150° C./4 hr | 150° C./4 hr | 150° C./4 hr | 150° C./4 hr |
| Hardness (type A) | 70 | 71 | 70 | 70 |
| Elongation (%) | 30 | 30 | 30 | 30 |
| Tensile strength (MPa) | 7 | 7 | 7 | 7 |
| PPA shear adhesive strength (MPa) | 5 | 4 | 5 | 5 |
| Cohesive failure rate (%) | 80 | 80 | 90 | 80 |

TABLE 2

| | Comparative | Comparative | Comparative |
|---|---|---|---|
| | example 1 | example 2 | example 3 |
| SiH/SiVi | 1.5 | 1.5 | 1.5 |
| External appearance | colorless and | colorless and | cloudy |
| | transparent | transparent | |
| Curing conditions | 150° C./4 hr | 150° C./4 hr | 150° C./4 hr |
| Hardness (type A) | 70 | 72 | 72 |
| Elongation (%) | 30 | 30 | 30 |
| Tensile strength (MPa) | 6 | 7 | 7 |
| PPA shear adhesive | 2 | 2 | 2 |
| strength (MPa) | | | |
| Cohesive failure rate (%) | 50 | 30 | 30 |

TABLE 3

| | | | | | Comparative | Comparative | Comparative |
|---|---|---|---|---|---|---|---|
| | Example 1 | Example 2 | Example 3 | Example 4 | example 1 | example 2 | example 3 |
| Immediately | 0 | 0 | 0 | 0 | 0 | 0 | 0 |
| after curing | | | | | | | |
| 120 hr | 0 | 0 | 0 | 0 | 10 | 5 | 0 |
| 240 hr | 0 | 0 | 0 | 0 | 80 | 80 | 0 |
| 500 hr | 0 | 0 | 0 | 0 | 100 | 100 | 0 |
| 750 hr | 0 | 0 | 0 | 0 | | | 0 |
| 1,000 hr | 0 | 0 | 0 | 0 | | | 0 |

n = 20 (sample size)

Comparative example 3 is a composition that does not satisfy the refractive index condition of the present invention. Although the device formed using this composition exhibited favorable thermal shock resistance properties, its transparency was inferior.

The composition of the present invention is ideal for encapsulating semiconductors, and particularly optical semiconductors.

What is claimed is:

1. A curable silicone rubber composition, comprising:
(A) a linear organopolysiloxane (A-1) represented by a general formula (1) shown below, having a viscosity at 25° C. within a range from 10 to 1,000,000 mPa·s, 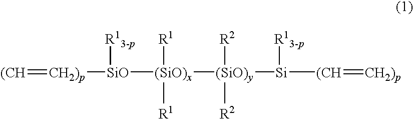
wherein each R¹ represents, independently, an unsubstituted or substituted monovalent hydrocarbon group, each R² represents, independently, an unsubstituted or substituted monovalent hydrocarbon group having no aliphatic unsaturated bonds, x and y each represents either 0 or a positive integer, provided that x+y is a number that yields a viscosity at 25° C. for the organopolysiloxane of 10 to 1,000,000 mPa·s, and p is an integer from 1 to 3, or
a mixture of the organopolysiloxane (A-1) and a resin-structure organopolysiloxane (A-2) composed of SiO₂ units, R³ₖR⁴ₚSiO_{0.5} units and R³_{q}R⁴ᵣSiO_{0.5} units, wherein R³ represents a vinyl group or allyl group, R⁴ represents a monovalent hydrocarbon group containing no aliphatic unsaturated bonds, k is 2 or 3 and p is 0 or 1, provided that k+p=3, q is 0 or 1 and r is 2 or 3, provided that q+r=3,
(B) an organohydrogenpolysiloxane having two or more SiH groups within each molecule,
(C) a metal-based condensation reaction catalyst,
(D) a platinum group metal-based addition reaction catalyst, and
(E) an organopolysiloxane-based adhesion-imparting agent containing at least two types of functional groups selected from the group consisting of alkenyl groups, alkoxy groups and epoxy group, wherein
among refractive indices of component (A), a mixture of component (A) and component (B), and component (E), a difference between a maximum refractive index and a minimum refractive index is not more than 0.03.

2. The curable silicone rubber composition according to claim 1, wherein among refractive indices of component (A), a mixture of component (A) and component (B), and component (E), a difference between a maximum refractive index and a minimum refractive index is not more than 0.02.

3. The curable silicone rubber composition according to claim 1, wherein component (A-2) is comprised within component (A) in an amount of from 20 to 70% by mass.

4. The curable silicone rubber composition according to claim 1, wherein component (A) and component (E) both contain no aromatic groups.

5. The curable silicone rubber composition according to claim 1, wherein at least one of component (A), component (B) and component (E) contains aromatic groups, and, among aromatic group mol % values of the components, a maximum value and a minimum value satisfy a formula shown below:
[(maximum value−minimum value)/maximum value]≦0.3.

6. The curable silicone rubber composition according to claim 1, comprising
component (B) in an amount sufficient to provide an amount of SiH groups within component (B) of 0.7 to 4.0 mols per mol of alkenyl groups within component (A),
component (E) in an amount of 0.01 to 10 parts by mass per 100 parts by mass of component (A),
component (C) in an amount of 0.005 to 10 parts by mass per 100 parts by mass of a combination of component (A) and component (E), and
component (D) in an amount sufficient to provide an equivalent mass of platinum group metal of 0.1 to 1,000 ppm relative to a mass of component (A).

7. The curable silicone rubber composition according to claim 1, wherein component (C) is an aluminum-based catalyst or a zirconium-based catalyst.

8. A semiconductor device, comprising a semiconductor chip, and a cured product of a curable silicone rubber composition that coats or encapsulates the chip, wherein the curable silicone rubber composition comprises:
A curable silicone rubber composition, comprising:
(A) a linear organopolysiloxane (A-1) represented by a general formula (1) shown below, having a viscosity at 25° C. within a range from 10 to 1,000,000 mPa·s, 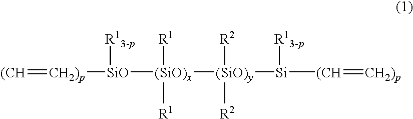
wherein each R¹ represents, independently, an unsubstituted or substituted monovalent hydrocarbon group, each R² represents, independently, an unsubstituted or substituted monovalent hydrocarbon group having no aliphatic unsaturated bonds, x and y each represents either 0 or a positive integer, provided that x+y is a number that yields a viscosity at 25° C. for the organopolysiloxane of 10 to 1,000,000 mPa·s, and p is an integer from 1 to 3, or
a mixture of the organopolysiloxane (A-1) and a resin-structure organopolysiloxane (A-2) composed of SiO₂ units, R³ₖR⁴ₚSiO_{0.5} units and R³_{q}R⁴ᵣSiO_{0.5} units, wherein R³ represents a vinyl group or allyl group, R⁴ represents a monovalent hydrocarbon group containing no aliphatic unsaturated bonds, k is 2 or 3 and p is 0 or 1, provided that k+p=3, q is 0 or 1 and r is 2 or 3, provided that q+r=3,
(B) an organohydrogenpolysiloxane having two or more SiH groups within each molecule,
(C) a metal-based condensation reaction catalyst,
(D) a platinum group metal-based addition reaction catalyst, and
(E) an organopolysiloxane-based adhesion-imparting agent containing at least two types of functional groups selected from the group consisting of alkenyl groups, alkoxy groups and epoxy group, wherein
among refractive indices of component (A), a mixture of component (A) and component (B), and component (E), a difference between a maximum refractive index and a minimum refractive index is not more than 0.03.
